(19) United States
(12) Patent Application Publication
(10) Pub. No.: US 2007/0267664 A1
(43) Pub. Date: Nov. 22, 2007

(54) SEMICONDUCTOR DEVICE AND METHOD OF MANUFACTURING THE SAME

(75) Inventors: Yasuto SUMI, Kawasaki-shi (JP); Masakatsu Takashita, Kawasaki-shi (JP); Masaru Izumisawa, Kawasaki-shi (JP); Hiroshi Ohta, Tokyo (JP); Wataru Saito, Kawasaki-shi (JP); Syotaro Ono, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/751,244

(22) Filed: May 21, 2007

(30) Foreign Application Priority Data
May 22, 2006 (JP) 2006-141004

(51) Int. Cl. H01L 29/76

(52) U.S. Cl. 257/288

(57) ABSTRACT

A semiconductor device according to the present invention comprises a first semiconductor layer of the first conductivity type. A pillar layer includes first semiconductor pillars of the first conductivity type and second semiconductor pillars of the second conductivity type arranged periodically and alternately on the first semiconductor layer. The first and second semiconductor pillar layer have a cross section in the shape of stripes in a planar direction. There is a semiconductor base layer of the second conductivity type selectively formed in a surface of the second semiconductor pillar, and a semiconductor diffusion layer of the first conductivity type selectively formed in a surface of the semiconductor base layer. The longitudinal direction of the shape of stripes is made almost same as the direction of pattern shift caused in the first semiconductor layer.

### CROSS REFERENCE TO RELATED APPLICATION

This application is based on and claims the benefit of priority from prior Japanese Patent Application No. 2006-141004, filed on May 22, 2006, the entire contents of which are incorporated herein by reference.

### BACKGROUND OF THE INVENTION

1. Field of the Invention

The present invention relates to a semiconductor device, and more particularly to a semiconductor device having a superjunction structure including p-type pillars and n-type pillars formed laterally and alternately in a drift layer, and a method of manufacturing such the semiconductor device.

2. Description of the Related Art

A vertical power MOSFET (Metal Oxide Semiconductor Field Effect Transistor) has an on-resistance, which greatly depends on the electric resistance in a conduction layer (drift layer) portion. The electric resistance in the conduction layer is determined from the impurity concentration thereof and an increased impurity concentration can lower the on-resistance. When the impurity concentration is made higher, however, a PN junction formed between the drift layer and the base layer is given a lowered breakdown voltage. Accordingly, the impurity concentration can not be made higher than a limit determined in accordance with the breakdown voltage. Thus, there is a trade-off between the device breakdown voltage and the on-resistance. An improvement in trade-off is a critical subject in providing a semiconductor device of lower power consumption. The trade-off has a limit determined from device material and going beyond the limit is a way to realize a semiconductor device with a lower on-resistance.

As an example of the MOSFET for solving the problem, there has been known a structure called superjunction in which p-type pillars and n-type pillars are formed in a drift layer laterally and alternately. The superjunction structure is employed to equalize the quantities of the charge (the quantities of the impurity) contained in the p-type pillar and the n-type pillar to create a non-doped layer artificially. This is effective to retain a higher breakdown voltage and make a current flow through the n-type pillar highly doped, thereby realizing a lower on-resistance beyond the material limit.

Such the superjunction structure can be formed through a method of repeating ion implantation and epitaxial growth (see JP 2001-119022A, for example), or a method of forming trenches in a semiconductor layer and then applying crystal growth to bury a semiconductor layer in the trenches.

In the former method of repeating ion implantation and epitaxial growth to form the superjunction structure, the ion implantation position in a lower epitaxial layer must be aligned with the ion implantation position in an upper epitaxial layer though misalignment may occur at that time. The occurrence of misalignment prevents vertical formation of the pillars that form the superjunction structure and may cause the following troubles possibly.

(1) The substantial length of the drift layer in the longitudinal direction elongates and the on-resistance in the semiconductor device increases.

(2) The superjunction structure can not be formed at a desired pitch. Even if it is formed, the charge balance between p/n-pillars is destroyed, thereby lowering the breakdown voltage of the semiconductor device.

(3) The misalignment between the ion implantation positions collapses the impurity concentration profile in each p/n-pillar.

Therefore, it is required to prevent misalignment on ion implantation from occurring, or prevent the performance of the semiconductor device from lowering even if misalignment occurs.

### SUMMARY OF THE INVENTION

In one aspect the present invention provides a semiconductor device, comprising: a first semiconductor layer of the first conductivity type; a pillar layer including first semiconductor pillars of the first conductivity type and second semiconductor pillars of the second conductivity type arranged periodically and alternately on the first semiconductor layer, the first and second semiconductor pillar layers having a cross section in the shape of stripes in a planar direction; a first main electrode electrically connected to the first semiconductor layer; a semiconductor base layer of the second conductivity type selectively formed in a surface of the second semiconductor pillar; a semiconductor diffusion layer of the first conductivity type selectively formed in a surface of the semiconductor base layer; a second main electrode formed to establish connection with the semiconductor base layer and the semiconductor diffusion layer; and a control electrode formed on an insulator along the semiconductor base layer, the semiconductor diffusion layer and the first semiconductor pillar, wherein the longitudinal direction of the shape of stripes is made almost same as the direction of pattern shift caused in the first semiconductor layer.

In an aspect the present invention provides a method of manufacturing a semiconductor device that comprises a pillar layer including first semiconductor pillars of the first conductivity type and second semiconductor pillars of the second conductivity type arranged periodically and alternately on a semiconductor substrate, the first and second semiconductor pillar layers having a cross section in the shape of stripes in a planar direction, wherein the semiconductor substrate has an offset against a certain surface orientation, wherein the pillar layer is formed through repeated executions of the step of growing an epitaxial layer of the first conductivity type over the semiconductor substrate and the step of performing ion implantation to the epitaxial layer, wherein the ion implantation is executed to the epitaxial layer in the lowermost layer, after performing alignment based on an alignment mark formed on the semiconductor substrate or the epitaxial layer, and executed to the epitaxial layer in an upper layer than the epitaxial layer in the lowermost layer, after performing the alignment based on an alignment mark to be pattern-shifted in accordance with the condition of epitaxial growth and the direction of the offset, while correcting ion implantation positions in consideration of the amount of pattern shift such that the pillar layer is formed almost vertical to the semiconductor substrate.

In another aspect the present invention provides a method of manufacturing a semiconductor device that comprises a pillar layer including first semiconductor pillars of the first conductivity type and second semiconductor pillars of the second conductivity type arranged periodically and alternately on a semiconductor substrate, the first and second semiconductor pillar layer having a cross section in the shape of stripe in a planar direction, wherein the semiconductor substrate has an offset against a certain surface orientation, wherein the pillar layer is formed through repeated executions of the step of growing an epitaxial layer of the first conductivity type over the semiconductor substrate and the step of performing ion implantation to the epitaxial layer, wherein the pillar layer is formed such that the longitudinal direction of the shape of stripes is made almost coincident with the direction of the offset.

### BRIEF DESCRIPTION OF THE DRAWINGS

FIG. 1 is across-sectional view (Y-Z plane) schematically showing the structure of a power MOSFET according to a first embodiment of the present invention.

FIG. 2 is a cross-sectional view (X-Y plane) schematically showing the structure of the power MOSFET according to the first embodiment.

FIG. 3 is a step diagram illustrative of the step of forming the superjunction structure portion (pillars 14, 15) in the power MOSFET according to the first embodiment.

FIG. 4 is a step diagram illustrative of the step of forming the superjunction structure portion (pillars 14, 15) in the power MOSFET according to the first embodiment.

FIG. 5 is a step diagram illustrative of the step of forming the superjunction structure portion (pillars 14, 15) in the power MOSFET according to the first embodiment.

FIG. 6 is a step diagram illustrative of the step of forming the superjunction structure portion (pillars 14, 15) in the power MOSFET according to the first embodiment.

FIG. 7 shows a wafer 12W for use in the drain layer 12 as a semiconductor substrate of the first embodiment.

FIG. 8 illustrates pattern shift of the alignment mark Mi and correction of the ion implantation position.

FIG. 9 shows a second embodiment of the present invention.

FIG. 10A illustrates the effect of the second embodiment.

FIG. 10B illustrates the effect of the second embodiment.

FIG. 11 is a cross-sectional view (Y-Z plane) schematically showing the structure of a power MOSFET according to a third embodiment of the present invention.

FIG. 12 illustrates a modification of the present invention.

FIG. 13 illustrates a modification of the present invention.

### DETAILED DESCRIPTION OF THE EMBODIMENTS

The embodiments of the present invention will now be described next in detail with reference to the drawings. In the following embodiments the first conductivity type is assumed as n-type and the second conductivity type as p-type.

### First Embodiment

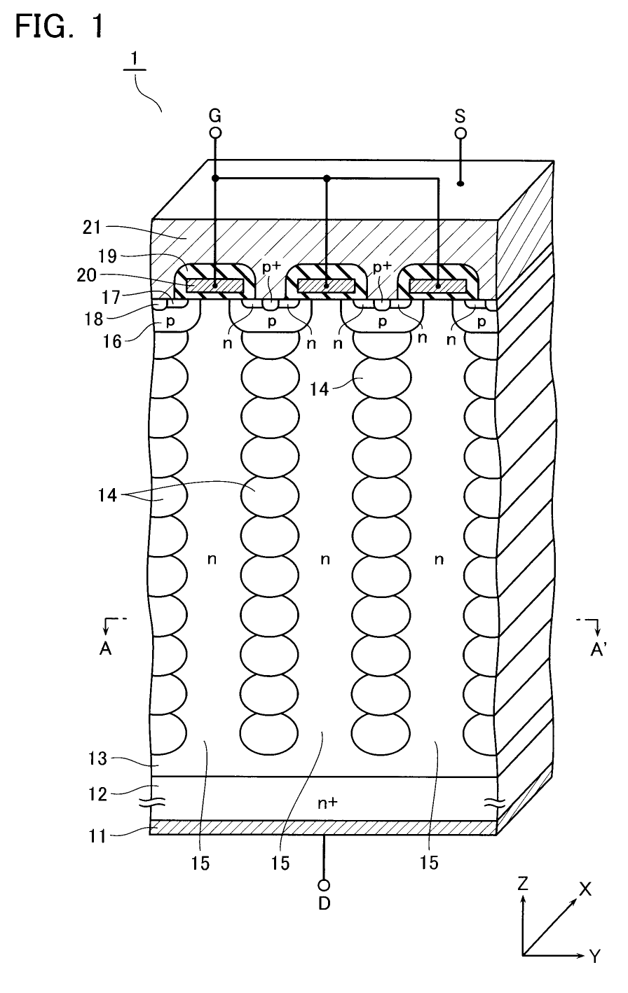

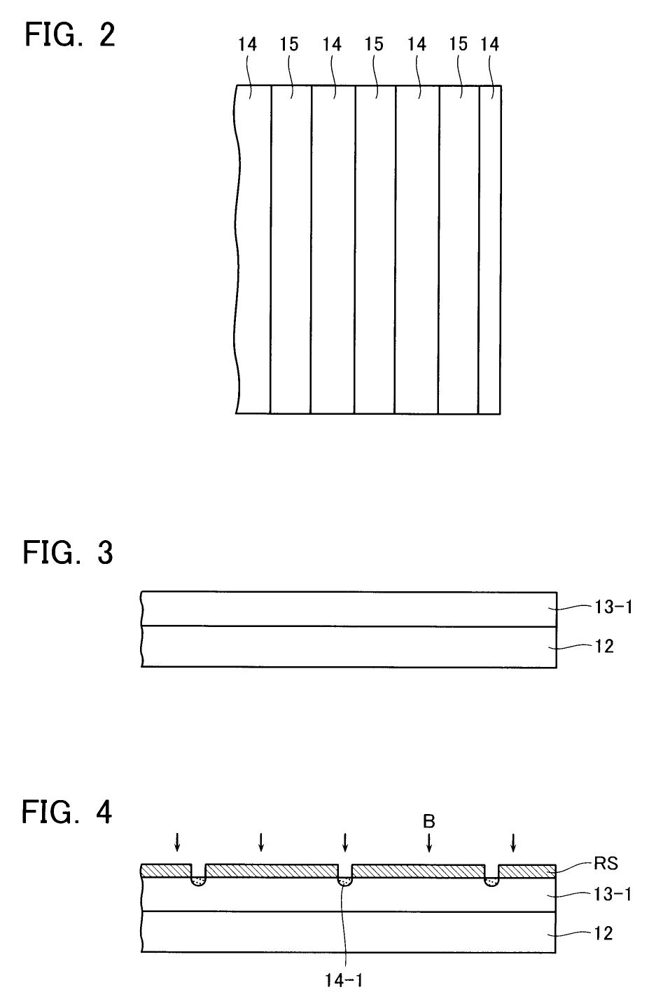

FIG. 1 is across-sectional view (Y-Z plane) schematically showing the structure of a power MOSFET according to a first embodiment of the present invention. The MOSFET comprises an n⁺-type drain layer 12 serving as a semiconductor substrate, on which an n-type epitaxial layer 13 is formed as a layer of n-type pillars 15. A plurality of p-type pillars 14 are formed in the n-type epitaxial layer 13 in the Y-direction at equal intervals. A superjunction structure is formed by the p-type pillars 14 and the n-type pillars 15 composed of the n-type epitaxial layer 13 located therebetween. The pillars 14, 15 are designed, as shown in the cross-sectional view (X-Y plane) in a plane of FIG. 2, to have horizontal a cross section in the shape of stripes extending in the X-axis direction.

In a surface of the p-type pillar 14, a p-type base layer 16 is selectively formed through diffusion. In a surface of the p-type base layer 16, an n-type source layer 17 and a p⁺-type contact layer 18 are selectively formed through diffusion. The p-type base layer 16 and the n-type source layer 17 are formed to have the shape of stripes extending in the X-axis direction similar to the p-type pillar 14 and the n-type pillar 15.

Over a region extending from a p-type base layer 16 and n-type source layer 17 through an n-type pillar 15 to an adjacent p-type base layer 16 and n-type source layer 17, a gate insulator 19 is formed. The gate insulator 19 may be composed of a silicon oxide with a film thickness of about 0.1 μm. On the gate insulator 19, a gate electrode 20 is formed in the shape of a stripe with the longitudinal direction in the X-axis direction. Sandwiching the gate electrode 20, on the p-type base layer 16 and the n-type source layer 17, a source electrode 21 is formed. The source electrode 21 is also formed in the shape of a stripe with the longitudinal direction in the X-direction similar to the n-type source layer 17 and so forth. On a lower surface of the n⁺-type drain layer 12, a drain electrode 11 is formed.

The steps of forming the superjunction structure portion (p-type pillars 14 and n-type pillars 15) are described with reference to FIGS. 3-6. First, as shown in FIG. 3, over the principal plane of a semiconductor wafer serving as the n⁺-type drain layer 12, an epitaxial layer 13-1 is grown, for example, around 5 μm as the n-type epitaxial layer 13.

Next, as shown in FIG. 4, after a resist film RS is formed over the epitaxial layer 13-1, the resist film RS is used as a mask to implant a p-type dopant such as boron (B) to form an impurity-implanted region 14-1 in the surface of the epitaxial layer 13-1. The mask has apertures, which are formed in the shape of stripes having the longitudinal direction in the X-axis direction at a certain pitch in accordance with the pn pitch in the superjunction structure to be formed. Therefore, the impurity-implanted region 14-1 also has the shape of a stripe with the longitudinal direction along the X-axis (three-dimensionally almost oblong columnar shape).

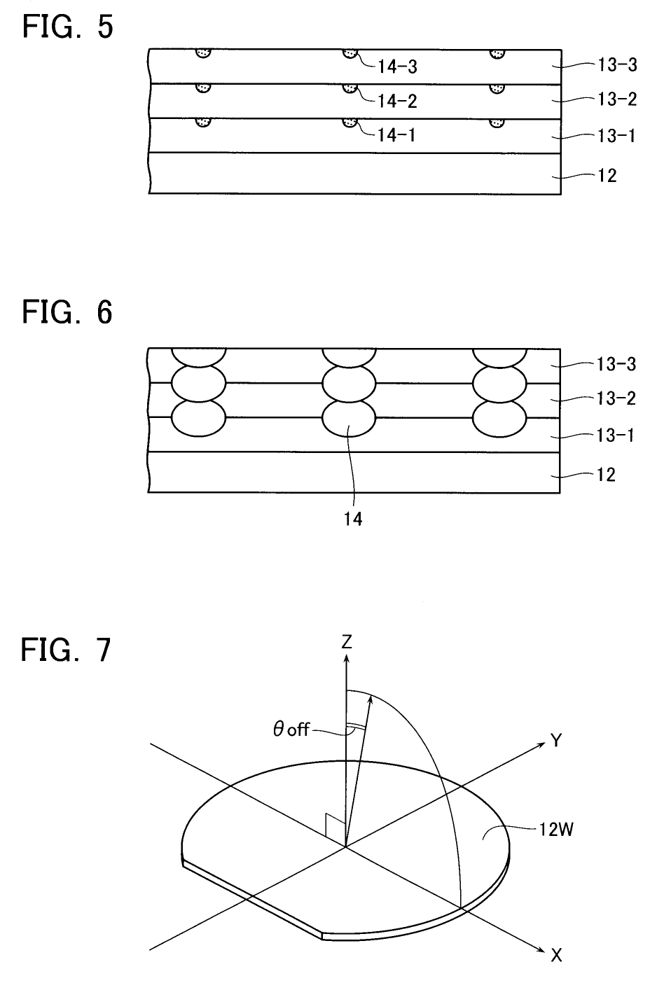

Next, as shown in FIG. 5, after the resist film RS is removed, an n-type epitaxial layer 13-2 is grown, for example, around 5 μm over the n-type epitaxial layer 13-1. Thereafter, a similar resist is used as a mask to implant boron into a portion immediately above the impurity-implanted region 14-1 to form an impurity-implanted region 14-2. Hereafter, a required number of steps are repeated similarly to grow an n-type epitaxial layer 13-i and then form an impurity-implanted region 14-i. Thereafter, a heat treatment is executed to diffuse impurity ions from the impurity-implanted regions 14-i arranged in a vertical direction to link the impurity-implanted regions, thereby forming the p-type pillars 14. At the same time, the n-type pillars 15 are formed therebetween.

Formation of the p-type pillar 14 extending almost straight in the vertical direction from the semiconductor substrate or the drain layer 12 requires the impurity-implanted regions 14-i to be formed immediately above the lower impurity-implanted region 14-i-1. Formation of the p-type pillar 14 or the n-type pillar 15 not extending straight almost in the vertical direction but extending in a slanting direction, or formation with winding, results in disadvantages such as an increase in on-resistance and a reduction in breakdown voltage of the MOSFET.

In order to position an ion implantation location of the impurity-implanted regions 14-i, an alignment mark (etched stair) is attached to a blank position on the drain layer 12 serving as the semiconductor substrate or on the epitaxial layer 13-1 as a sign of the ion implantation location.

Even after an upper epitaxial layer 13-i is additionally stacked, the alignment mark (stair) appears (as the stair) in the additionally stacked epitaxial layer 13-i. In this case, the so-called offset-less wafer (a wafer having a surface orientation along an ingot-slicing plane) may be employed as the semiconductor substrate for use in the drain layer 12. After multiple epitaxial layers are repeatedly deposited, the so-called washout phenomenon arises in which the stair of the alignment mark disappears from the upper epitaxial layer 13-i. In this case, it is required to reform the alignment mark through etching or the like, which increases the number of process steps.

For a precaution against this, the present embodiment uses, as the drain layer 12 or the semiconductor substrate, a [111] wafer (or [100] wafer) 12W having an offset direction (offset angle θoff) 3-5° tilted as shown in FIG. 7. The use of the wafer 12W having such the offset causes no washout phenomenon and therefore the alignment mark does not disappear.

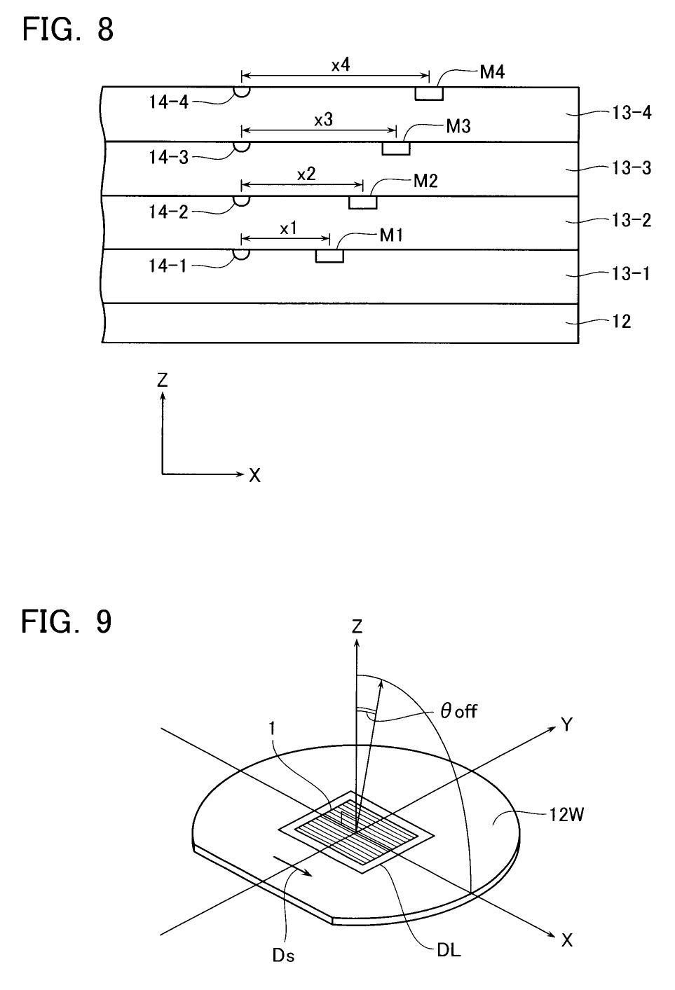

The presence of such the offset, however, causes the so-called pattern shift. The pattern shift refers to a phenomenon in which, relative to the position of a stair formed on a lower semiconductor layer, for example, a position of a stair reflected on an epitaxial layer deposited on the upper surface thereof shifts. Namely, formation of the superjunction structure includes forming an alignment mark M1 on a blank position in the lowermost epitaxial layer 13-1, and performing ion implantation relative to the alignment mark M1 as shown in FIG. 8. When an epitaxial layer 13-2 is additionally stacked on the epitaxial layer 13-1, an alignment mark M2 does not disappear but appears also in the epitaxial layer 13-2 based on the stair of the alignment mark M1. The position of appearance of the alignment mark M2, however, is not immediately above the alignment mark M1 in the lower layer. Instead, it shifts in a slanting direction in accordance with the offset direction, which varies based on the conditions of epitaxial growth (the growth rate, time, and temperature, the types of gases used, and so forth).

An alignment mark Mi on an upper epitaxial layer 13-i similarly suffers an occurrence of pattern shift. As long as the conditions of epitaxial growth are grasped, though, the amount of the shift of the alignment mark Mi can be held.

In the present embodiment, the amount of the shift is calculated in accordance with the conditions of epitaxial growth, and the shift is taken into account to correct the ion implantation position such that the impurity-implanted regions 14-1, 14-2, . . . , 14-i align straight almost in the vertical direction relative to the semiconductor substrate or the drain layer 12, as specifically described along FIG. 8. In the epitaxial layer 13-1, ion implantation is executed to a position at a distance x1 from an alignment mark M1 in the x-direction. On the other hand, in the epitaxial layer 13-2 deposited over the epitaxial layer 13-1, ion implantation is executed to a position at a distance x2 from an alignment mark M2 in the x-direction. The distance x2 is calculated from parameters, or the offset direction and the condition of epitaxial growth of the epitaxial layer 13-2, such that the impurity-implanted region 14-2 locates immediately above the impurity-implanted region 14-1. Hereinafter, also in an upper epitaxial layer 13-i, the amount of a shift is calculated similarly and the shift is taken into account to correct a distance xi. As a result, the pillar 14 can be formed extending straight almost in the vertical direction relative to the semiconductor substrate or the drain layer 12. The alignment mark M1 may be etched in the epitaxial layer 13-1. Alternatively, if an alignment mark (M0) is formed in the drain layer 12, an alignment mark M1, which can be obtained by pattern-shifting alignment mark M0, may be formed in the epitaxial layer 13-1.

### Second Embodiment

A power MOSFET according to a second embodiment of the present invention is described next with reference to FIG. 9. The power MOSFET of the present embodiment is almost similar in structure to that shown in FIG. 1 and has the superjunction structure in common. The wafer 12W having the offset direction (offset angle θoff) 3-5° tilted is used as the drain layer 12 or the semiconductor substrate, similar to the first embodiment.

In this embodiment, however, the superjunction structure has the longitudinal direction Ds of the shape of stripes in horizontal cross section made almost same as the offset direction, as shown in FIG. 9, different from the first embodiment. The term “almost same” herein means that an angular difference between the offset direction and the longitudinal direction Ds of the shape of stripes is equal to or less than ±1%.

The offset direction may be not same as the longitudinal direction Ds of the shape of stripes, for example, both may have a difference of 90° therebetween. Even in such the case, execution of the correction as described in FIG. 8 for the first embodiment makes it possible to form the pillars 14, 15 straight almost in the vertical direction. The condition of epitaxial growth may fluctuate and cause an error in the thickness of each epitaxial layer 13-i and so forth. In such the case, an accurate correction is made difficult, and therefore the pillars 14, 15 can not be formed straight in the vertical direction.

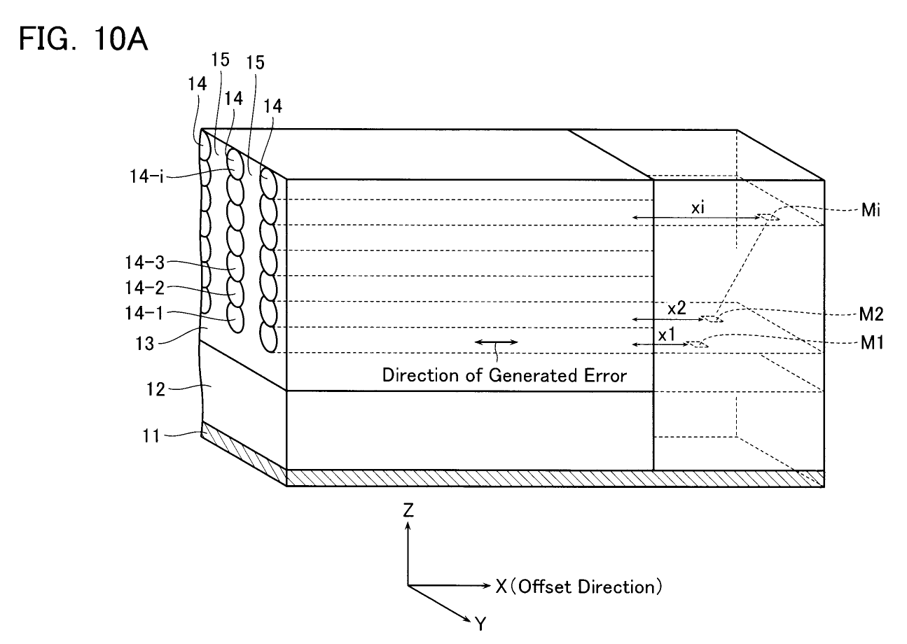

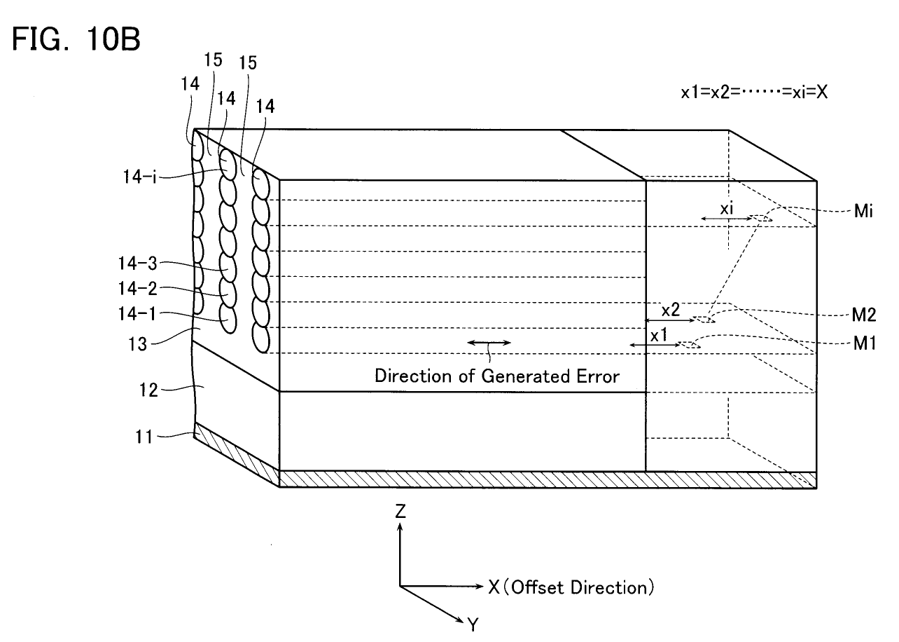

The effect of the present embodiment is described with reference to FIG. 10A. The offset direction is set in the x-direction that is almost coincident with the longitudinal direction of the shape of stripes of the pillars 14, 15. Therefore, the positions of the alignment marks M1, M2, . . . , Mi also shift farther in the X-direction on an upper epitaxial layer than a lower one (see FIG. 10A).

The position of the alignment mark Mi can be calculated in accordance with the condition of epitaxial growth of the epitaxial layer 13-i, and the correction as described in FIG. 8 makes it possible to form the pillars 14, 15 straight almost in the vertical direction. Due to the fluctuation of the condition of epitaxial growth of the epitaxial layer and so forth, however, a little error arises. On the contrary, in the present embodiment, the longitudinal direction of the shape of stripes of the pillars 14 is almost coincident with the offset direction. Therefore, even if the error as described above arises, an error in the position to form the pillar 14 arises in the longitudinal direction or the X-direction and causes no error in the pn pitch direction, that is, the Y-direction. Therefore, even under an environment that causes errors, the pillars can be formed straight almost in the vertical direction relative to the semiconductor substrate. Accordingly, it is possible to prevent occurrences of the following problems: (1) the substantial length of the drift layer in the longitudinal direction elongates and the on-resistance in the semiconductor device increases; (2) the superjunction structure can not be formed at a desired pitch and, even if it is formed, the charge balance between p/n-pillars is destroyed; (3) the misalignment between the ion implantation positions collapses the impurity concentration profile in each p/n-pillar.

In this embodiment, ion implantation may be executed to positions at an equidistance X (fixed) from the formed alignment marks M1, M2, . . . , Mi, as shown in FIG. 10B, without executing the above correction entirely. This process results in no influence on the pn pitch in the superjunction and forms the pillars straight almost in the vertical direction relative to the semiconductor substrate, with no influence exerted on the function of the superjunction structure.

### Third Embodiment

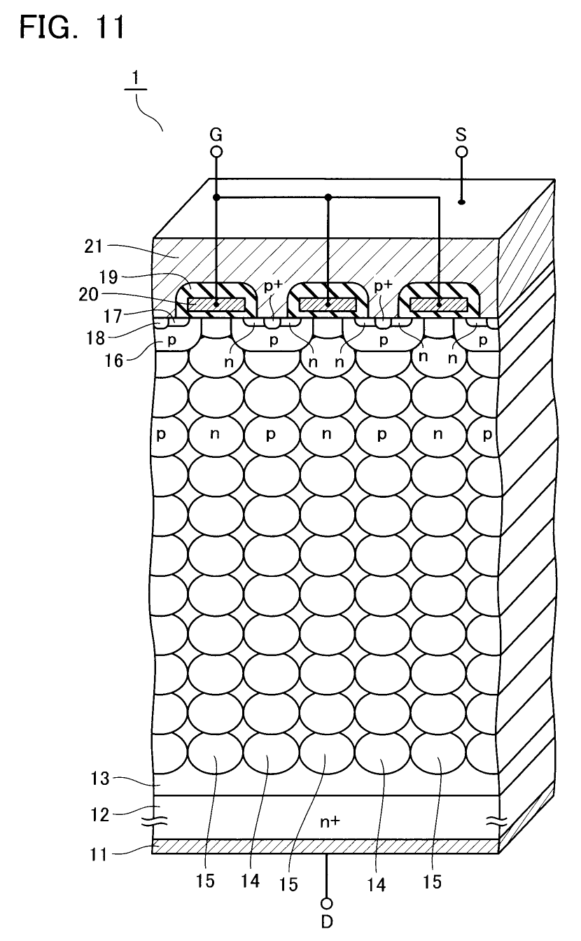

A power MOSFET according to a third embodiment of the present invention is described next with reference to FIG. 11. The power MOSFET of the present embodiment has a superjunction structure in common with the first embodiment. Different from the first embodiment, however, not only the p-type dopant is implanted into the epitaxial layer 13 but also an n-type dopant (such as phosphorous (P)) is implanted therebetween to form the pillars 15 as shown in FIG. 11. Namely, in the power MOSFET of this embodiment, through the steps shown in FIGS. 3-6, the n-type dopant is implanted between the p-type dopant-implanted portions (the impurity-implanted regions 14-i). Other points are similar to those in the first embodiment.

### Others

The embodiments of the invention are described above though the present invention is not limited to these embodiments but rather can be given various modifications and additions without departing from the scope and spirit of the invention.

For example, in the above embodiments, the first conductivity type is described as n-type and the second conductivity type as p-type. The present invention is also achievable when the first conductivity type is p-type and the second conductivity type is n-type. In the above embodiments, ions of the p-type impurity (and additionally the n-type impurity) are implanted into the n-type epitaxial layer 13 to form the superjunction structure. In contrast, an n-type impurity (such as phosphorous) may be implanted into a p-type epitaxial layer to form a superjunction structure.

The described MOSFET uses silicon (Si) as a semiconductor though available semiconductors may include a compound semiconductor such as silicon carbide (SiC) and gallium nitride (GaN), and a wide bandgap semiconductor such as diamond.

The exemplified MOSFET has the superjunction structure though the structure of the present invention is also applicable to devices having a superjunction structure, such as an SBD (Schottky Barrie Diode), a MOSFET and SBD device, an SIT (Static Induction Transistor), and an IGBT (Insulated Gate Bipolar Transistor). The MOSFET exemplified in the above embodiments has the so-called planar gate electrode though the present invention is also applicable to the so-called trench gate MOSFET that includes a gate electrode buried in a trench formed in a base layer with an insulator interposed therebetween, needless to say.

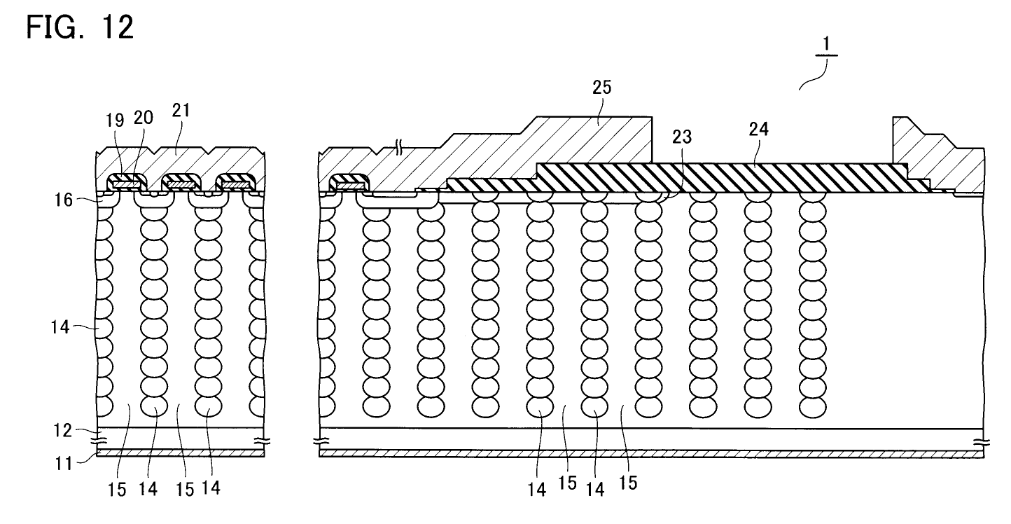

In addition, the superjunction structure can be formed not only in a device region where MOSFET cells are formed but also in a terminal region that surrounds the device region as shown in FIG. 12. In FIG. 12, the reference numeral 23 denotes a RESURF region, 24 a field plate insulator, 25 a field plate electrode.

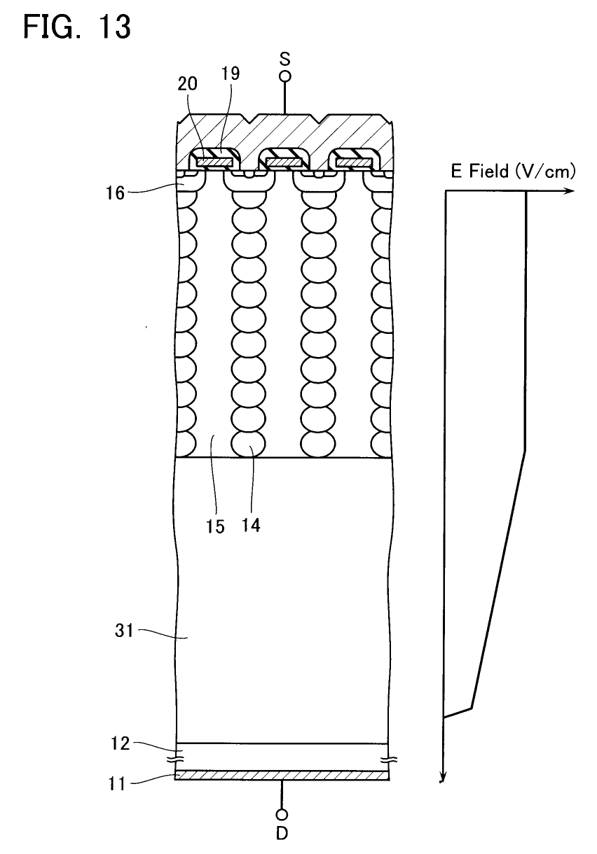

Further, beneath the superjunction structure including the p-type pillars 14 and the n-type pillars 15, an n⁻-type epitaxial layer 31 can be formed as shown in FIG. 13. In this case, the electric field is uniform throughout the superjunction structure portion while the MOSFET is turned off. In contrast, the electric field gradually lowers within the n⁻-type epitaxial layer 31 as the depth increases. Even in this case, the portion of the n⁻-type epitaxial layer 31 also retains a breakdown voltage. Accordingly, the overall breakdown voltage of the device can be enhanced correspondingly. In this example, the n⁻-type epitaxial layer 31 serves as the semiconductor substrate relative to the pillars.

What is claimed is:

1. A semiconductor device, comprising:
a first semiconductor layer of the first conductivity type;
a pillar layer including first semiconductor pillars of the first conductivity type and second semiconductor pillars of the second conductivity type arranged periodically and alternately on said first semiconductor layer, said first and second semiconductor pillar layers having a cross section in the shape of stripes in a planar direction;
a first main electrode electrically connected to said first semiconductor layer;
a semiconductor base layer of the second conductivity type selectively formed in a surface of said second semiconductor pillar;
a semiconductor diffusion layer of the first conductivity type selectively formed in a surface of said semiconductor base layer;
a second main electrode formed to establish connection with said semiconductor base layer and said semiconductor diffusion layer; and
a control electrode formed on an insulator along said semiconductor base layer, said semiconductor diffusion layer and said first semiconductor pillar,
wherein the longitudinal direction of said shape of stripes is made almost same as the direction of pattern shift caused in said first semiconductor layer.

2. The semiconductor device according to claim 1, wherein said first semiconductor layer comprises a wafer having an offset against a certain surface orientation, wherein the direction of said offset is made almost same as the longitudinal direction of said shape of stripes.

3. The semiconductor device according to claim 2, wherein said wafer is a [111] wafer or a [100] wafer.

4. The semiconductor device according to claim 2, wherein said pillar layer is formed through repeated executions of the step of growing an epitaxial layer of the first conductivity type over said first semiconductor layer and the step of performing ion implantation to said epitaxial layer.

5. The semiconductor device according to claim 1, further comprising an epitaxial layer of the first conductivity type formed between said pillar layer and said first semiconductor layer.

6. A method of manufacturing a semiconductor device that comprises a pillar layer including first semiconductor pillars of the first conductivity type and second semiconductor pillars of the second conductivity type arranged periodically and alternately on a semiconductor substrate, said first and second semiconductor pillar layers having a cross section in the shape of stripes in a planar direction,
wherein said semiconductor substrate has an offset against a certain surface orientation,
wherein said pillar layer is formed through repeated executions of the step of growing an epitaxial layer of the first conductivity type over said semiconductor substrate and the step of performing ion implantation to said epitaxial layer,
wherein said ion implantation is executed to said epitaxial layer in the lowermost layer, after performing alignment based on an alignment mark formed on said semiconductor substrate or said epitaxial layer, and executed to said epitaxial layer in an upper layer than said epitaxial layer in the lowermost layer, after performing said alignment based on an alignment mark to be pattern-shifted in accordance with the condition of epitaxial growth and the direction of said offset, while correcting ion implantation positions in consideration of the amount of pattern shift such that said pillar layer is formed almost vertical to said semiconductor substrate.

7. The method of manufacturing according to claim 6, wherein said ion implantation is executed by implanting ions of the second conductivity type.

8. The method of manufacturing according to claim 6, wherein said ion implantation is executed by implanting ions of the first conductivity type and ions of the second conductivity type.

9. The method of manufacturing according to claim 6, wherein the longitudinal direction of said shape of stripes in said pillar layer is made almost coincident with the direction of said offset.

10. A method of manufacturing a semiconductor device that comprises a pillar layer including first semiconductor pillars of the first conductivity type and second semiconductor pillars of the second conductivity type arranged periodically and alternately on a semiconductor substrate, said first and second semiconductor pillar layer having a cross section in the shape of stripes in a planar direction and,
wherein said semiconductor substrate has an offset against a certain surface orientation,
wherein said pillar layer is formed through repeated executions of the step of growing an epitaxial layer of the first conductivity type over said semiconductor substrate and the step of performing ion implantation to said epitaxial layer,
wherein said pillar layer is formed such that the longitudinal direction of said shape of stripes is made almost coincident with the direction of said offset.

11. The method of manufacturing according to claim 10, wherein said semiconductor substrate or said epitaxial layer has an alignment mark formed thereon, wherein said ion implantation is executed by implanting ions to positions at an equidistance from said alignment mark.

12. The method of manufacturing according to claim 10, wherein said ion implantation is executed by implanting ions of the second conductivity type.

13. The method of manufacturing according to claim 10, wherein said ion implantation is executed by implanting ions of the first conductivity type and ions of the second conductivity type.
